(19) United States
(12) Patent Application Publication
(10) Pub. No.: US 2002/0146050 A1
(43) Pub. Date: Oct. 10, 2002

(54) Semiconductor laser device

(75) Inventors: Norihiro Iwai, Tokyo (JP); Masaki Funabashi, Tokyo (JP); Toshikazu Mukaihara, Tokyo (JP); Akihiko Kasukawa, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC Co., Ltd., Chiyoda-ku (JP)

(21) Appl. No.: 09/828,144

(22) Filed: Apr. 9, 2001

(51) Int. Cl. H01S 5/00

(52) U.S. Cl. 372/46

(57) ABSTRACT

A semiconductor laser device comprising a substrate, a resonator overlying said substrate, a waveguide overlying said substrate and optically coupled to said resonator, and a diffraction grating formed on said resonator or said waveguide, said diffraction grating including slits or grooves formed on an Al-oxidized region of an Al-containing oxidized semiconductor layer, said Al-oxidized region being formed by selectively oxidizing Al in said Al-containing oxidized semiconductor layer. In the present invention, the difference between the refractive indices of the layer having the embedded grating and the Al oxide layer becomes larger to increase the coupling constant between laser beams and the grating. The decrease of the cavity length can increase the number of the devices obtainable from a single wafer.

### BACKGROUND OF THE INVENTION

(a) Field of the Invention

The present invention relates to a semiconductor laser device including a diffraction grating, and more in detail to the semiconductor laser device having a structure which allows the number of the laser devices obtainable from a single wafer to be increased. Especially, the semiconductor laser device of the present invention has a configuration with which the cavity length of the semiconductor laser device can be reduced.

(b) Description of the Related Art

A distributed feedback (DFB) semiconductor laser includes a grating (diffraction grating) adjacent to an active layer. The reflection occurs only at a specified wavelength determined by a pitch (λ/4n) of the grating. A single longitudinal mode operation can be performed because the emission occurs only at the selected wavelength. Thus, the DFB laser is frequently used as a light source for optical communication because the emission occurs only at the

The configuration of the conventional DFB semiconductor laser device will be described with reference to FIG. 1.

The DFB semiconductor laser device 25 having an emission wavelength of 1.55 μm includes a stacked structure formed by epitaxially growing an n-InP cladding layer 12, an SCH-MQW active layer 13, a p-InP cladding layer 14, a p-GaInAsP [λg (bandgap wavelength)=1.1 μm] waveguide layer 15 on an InP substrate 11, in this order, etching the waveguide layer 15 to form a grating (diffraction grating) 15A and depositing a p-InP cladding layer 16 by using an MOCVD Metal Oxide Chemical Vapor Deposition) method for embedding the grating 15A.

The SCH-MQW active layer 13 lases at a wavelength of 1.55 μm, and the grooves of the grating are formed at a pitch of approximately 240 nm (λ=1.55 μm).

As shown in FIG. 1, the p-InP cladding layer 16, the waveguide layer 15, the p-InP cladding layer 14 and the active layer 13 and the top portion of the n-InP cladding layer 12 of the stacked structure are etched to form mesa stripe having a width of about 1.5 μm.

Both sides of the mesa stripe are buried with current blocking layers formed by a p-InP layer 17 and an n-InP layer 18 grown by an MOCVD method by using a selective growth technique.

A p-InP cladding layer 19 and a p-GaInAs contact layer 20 are formed on the mesa stripe and the current blocking layers in this order by using the MOCVD method. A p-side electrode 21 and an n-side electrode 22 are formed on the contact layer 20 and the bottom surface of the substrate 11, respectively.

Then, a method for fabricating the conventional DFB semiconductor laser will be described by referring to FIGS. 2A to 2F.

As shown in FIG. 2A, the n-InP cladding layer 12, the SCH-MQW active layer 13 emitting at a wavelength of 1.55 μm, the p-InP cladding layer 14 and the p-GaInAsP (λg=1.1 μm) waveguide layer 15 are sequentially and epitaxially grown overlying the n-InP substrate 11 by using the MOCVD method.

After a grating (diffraction grating) pattern having a pitch of 240 nm (λ=1.55 μm) is formed on the waveguide layer 15 by using a photolithographic technology and an interference aligner, the grating 15A is formed as shown in FIG. 2B by chemically etching the waveguide layer 15.

Then, as shown in FIG. 2C, the p-InP cladding layer 16 is epitaxially grown on the waveguide layer (grating) 15 by using the MOCVD method to embed the grating 15A therein.

After an SiNₓ film is deposited on the P-InP layer 16 followed by the patterning for forming an etching mask 23, the p-InP cladding layer 16, the waveguide layer 15 (grating 15A), the p-InP cladding layer 14, the active layer 13 and the top portion of the n-InP cladding layer 12 are etched by using the etching mask 23 and a dry etching process with bromine-based etching liquid, thereby forming the mesa stripe having the width of about 1.5 μm, as shown in FIG. 2D.

Then, as shown in FIG. 2E, the current blocking layer formed by the p-InP layer 17 and the n-InP layer 18 are selectively grown on the region excluding the mesa top by using the etching mask as a selective growth mask by means of the MOCVD method.

After the removal of the etching mask 23, the p-InP cladding layer 19 and the p-GaInAs contact layer 20 are formed in this order on the mesa stripe and the current blocking layer by using the MOCVD method.

Finally, the p-side electrode 21 and the n-side electrode 22 are formed to provide the DFB semiconductor laser device as shown in FIG. 1.

Since the coupling efficiency between the laser beams and the diffraction grating is small in the conventional DFB semiconductor laser device, the cavity length should be rather longer, for example, between 400 and 600 μm, for increasing the probability of the single longitudinal mode.

The increase of the cavity length reduces the number of the semiconductor laser devices obtainable from a single wafer, which raises the fabrication cost of the semiconductor laser device.

### SUMMARY OF THE INVENTION

In view of the foregoing, an object of the present invention is to provide a semiconductor laser device with a reduced cavity length, thereby increasing the number of the semiconductor laser devices obtainable from a single wafer.

Thus, the present invention provides a semiconductor laser device including a substrate, a resonator overlying said substrate, a waveguide overlying said substrate and optically coupled to said resonator, and a diffraction grating formed on said resonator or said waveguide, said diffraction grating including slits or grooves formed on an Al-oxidized region of an Al-containing oxidized semiconductor layer, said Al-oxidized region being formed by selectively oxidizing Al in said Al-containing oxidized semiconductor layer.

In accordance with the present invention, the refractive index of the Al-containing oxidized semiconductor layer is reduced as low as to about 2.4 by converting the Al-containing oxidized semiconductor layer into the Al oxide layer by means of the oxidation, and the difference between the refractive indices of the layer having the embedded grating and the Al oxide layer becomes larger. Since the difference between the refractive indices can be made larger, the coupling constant between laser beams and the grating can be made larger, and even if the cavity length is reduced, the single longitudinal mode operation can be securely performed. The shortening of the cavity length of the semiconductor laser device can increase the number of the devices obtainable from a single wafer, thereby realizing the fabrication of the semiconductor laser device with lower cost.

The above and other objects, features and advantages of the present invention will be more apparent from the following description.

### BRIEF DESCRIPTION OF DRAWINGS

FIG. 1 is a longitudinal sectional view showing a conventional DFB semiconductor laser device.

FIGS. 2A to 2F are longitudinal sectional views of the semiconductor laser device of FIG. 1 sequentially showing a method for fabricating the semiconductor laser device.

FIG. 3 is a longitudinal sectional view showing a semiconductor laser device in accordance with an embodiment of the present invention.

FIG. 4 is a longitudinal sectional view showing the semiconductor laser device of FIG. 3 taken along a line I-I in FIG. 3 or along a direction parallel to that of a resonator.

FIGS. 5A, 5C to 5E are longitudinal sectional views of the semiconductor laser device of FIG. 3 sequentially showing a method for fabricating the semiconductor laser device, and FIG. 5B is a longitudinal sectional view showing the semiconductor laser device of FIG. 5A taken along a line II-II in FIG. 5A.

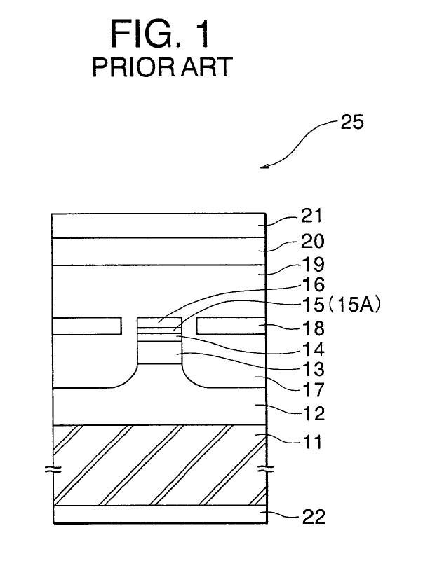

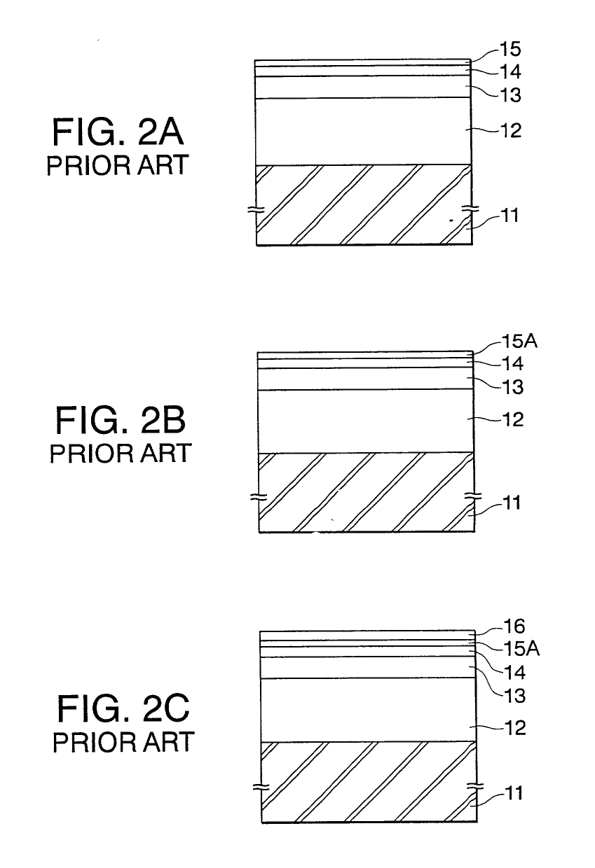

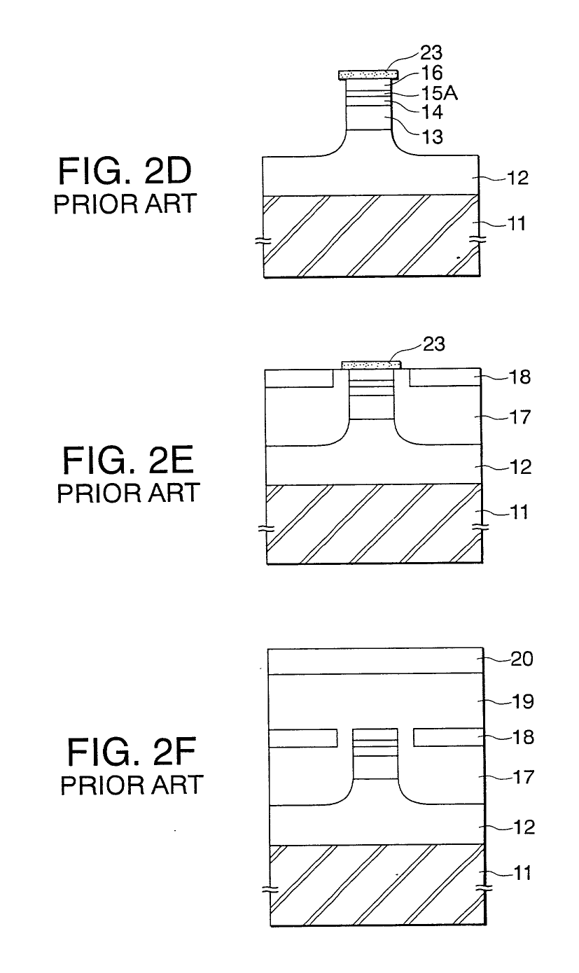

### PREFERRED EMBODIMENTS OF THE INVENTION

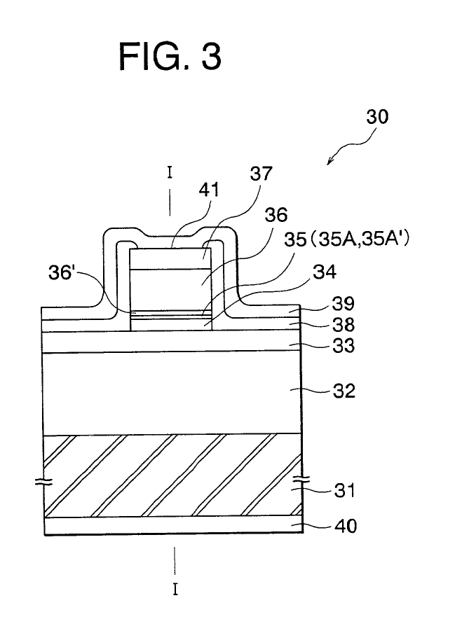

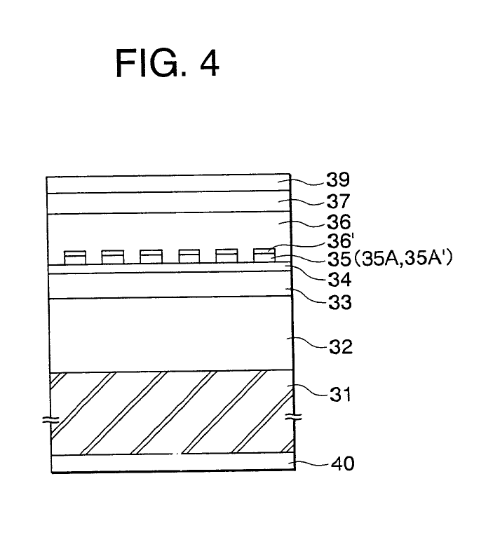

Then, the configuration of a semiconductor laser device of an embodiment will be described referring to FIGS. 3 and 4.

As shown in FIG. 3, the semiconductor laser device 30 of the embodiment having an emission wavelength of 1.55 μm includes a stacked structure formed by an n-InP cladding layer 32, an SCH-MQW active layer 33 emitting at a wavelength of 1.55 μm, a p-InP cladding layer 34, a grating (diffraction grating) 35A′, a p-InP protective layer 36′ having the grating shape formed on the grating 35A′, a p-InP layer 36 for embedding the p-InP protective layer 36′ and the grating 35A′, and a p-GaInAs contact layer 37 sequentially and epitaxially grown on an n-InP substrate 31 having a thickness of about 100 μm by using the MOCVD method.

As shown in FIG. 4, the gratings 35A′ are formed by a plenty of Al oxide layers 35A separated among one another at a pitch of approximately 240 nm (λ=1.55 μm) and having a fine width arranged on the p-InP cladding layer 34. A p-InP embedded layer having a narrower width and formed with the filling of the p-InP layer 36 is formed between the adjacent Al oxide layers 35A.

The grating 35A′ made of the Al oxide layer 35A is formed, as described below, by patterning the p-AlInAs layer 35 to the grating shape, and selectively oxidizing the Al in the patterned p-AlInAs layer 35, and includes, as a protective layer for patterning the p-AlInAs layer 35, the p-InP protective layer 36′ on the Al oxide layer 35A.

The p-InP cladding layer 34, the Al oxide layer 35A (grating 35A′), the p-InP protective layer 36′, the p-InP layer 36 and the contact layer 37 overlying the active layer 33 are etched to form a striped ridge.

An SiNₓ film 38 acting as a dielectric film is formed on the top of the ridge excluding a window 41 for exposing the contact layer 37, and a p-side electrode 39 is formed on the SiNₓ film 38 and the window 41. An n-side electrode 40 is formed on the bottom surface of the n-InP substrate 31.

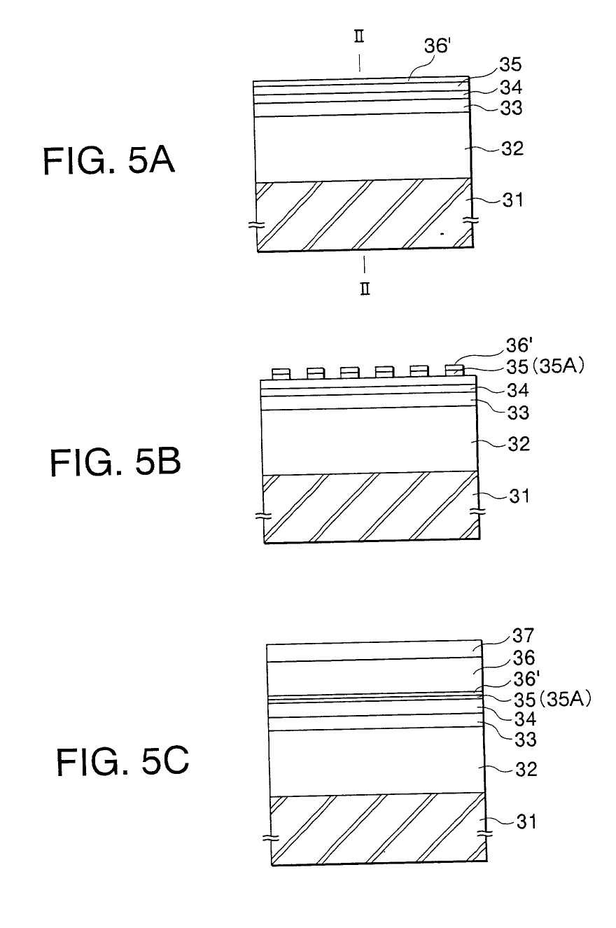

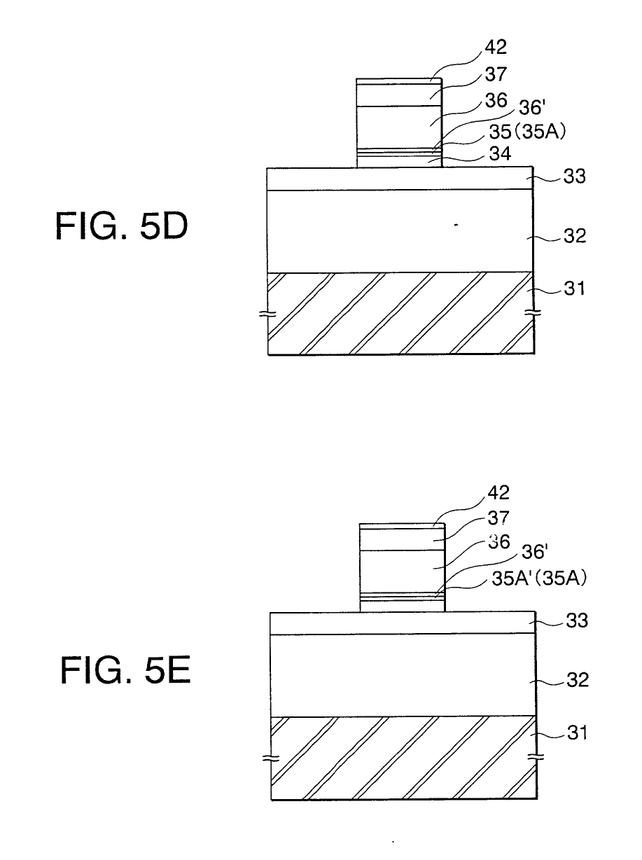

Then, a method for fabricating the DFB semiconductor laser device of the embodiment will be described by referring to FIGS. 5A to 5E.

As shown in FIG. 5A, the n-InP cladding layer 32, the SCH-MQW active layer 33 emitting at a wavelength of 1.55 μm, the p-InP cladding layer 34, the p-AlInAs layer 35 and the p-InP protective layer 36′ are sequentially and epitaxially grown to form a stacked structure on the nInP substrate 31 by using the MOCVD method.

After a grating (diffraction grating) pattern having a pitch of 240 nm (λ=1.55 μm) is formed on the p-InP protective layer 36′ by using a photolithographic technology and an interference aligner, the p-AlInAs layer 35 and the p-InP protective layer 36′ are dry-etched to form grating-like layers 35A and 36′, as shown in FIG. 5B.

Then, as shown in FIG. 5C, the p-InP layer 36 is epitaxially grown for embedding the grating-like p-InP protective layer 36′ and the p-AlInAs layer 35A by using the MOCVD method, and further grown thereon. Then, the p-GaInAs contact layer 37 is stacked on the p-InP layer 36.

As shown in FIG. 5D, after the SiO₂ film is deposited on the contact layer 37 followed by the patterning for forming an etching mask 42, the contact layer 37, the pInP layer 36, the P-InP protective layer 36′, the gratinglike p-AlInAs layer 35A and the p-InP cladding layer 34 are etched by using the etching mask 42 to form the striped ridge having a width of 10 μm. Thereby, the active layer 33 is exposed to both side of the ridge and also the grating-like AlInAs layer 35 is exposed to the ridge side surfaces.

The stacked structure having the striped ridge with the etching mask 42 is thermally treated in an water vapor ambient at a temperature of about 500° C. for 150 minutes to oxidize the entire layer of the grating-like AlInAs layer 35, thereby converting the AlInAs layer 35 into the Al oxide layer 35A to form the grating 35A′ as shown in FIG. 5E.

After the removal of the etching mask 42, the SiNₓ film 38 is deposited on the top surface of the ridge excluding the window 41 for exposing the contact layer 37 and the p-side electrode 39 is formed on the window 41 and the SiNₓ film 38.

After the bottom surface of the n-InP substrate 31 is polished until the substrate thickness becomes about 100 μm, the n-side electrode 40 is formed on the bottom surface of the n-InP substrate 31.

Since the refractive index of the AlInAs layer 35 of the DFB semiconductor laser device 30 fabricated in accordance with the above procedures is reduced as low as to about 2.4 by converting the AlInAs layer 35 into the Al oxide layer 35A by means of the oxidation, the difference between the refractive indices of the InP layer 36 having the embedded grating 35A′ and the Al oxide layer 35A becomes larger.

Since the difference between the refractive indices can be made larger in the DFB semiconductor laser device having the grating made of the Al oxide layer of the embodiment, the coupling constant between laser beams and the grating can be made larger, and even if the cavity length is reduced, the single longitudinal mode operation can be securely performed.

Another merit of reducing the cavity length of the semiconductor laser device includes the remarkable improvement of the single mode performance because the longitudinal mode spacing is extended.

Although the above embodiment has been described in connection with the DFB semiconductor laser device, the present invention can be applied to a distributed Bragg reflector (DBR) semiconductor laser device provided that a diffraction grating is formed by an Al-containing oxidized semiconductor layer, and the Al in the Al-containing oxidized semiconductor layer can be selectively oxidized to form the grating made of the Al oxide layer.

The device structure is not restricted to the ridge waveguide structure of the embodiment, and can be applied, for example, to an embedded structure having a current confinement structure formed by an Al oxide layer (ACIS)(IEEE Journal of Selected Topics in Quantum Electronics, vol.5, no.3, p694 (1999)). The embedded structure is economical because an oxide layer for the current confinement structure and another oxide layer for the diffraction grating can be simultaneously formed by selectively oxidizing the Al in the Al-containing oxidized semiconductor layer, thereby reducing the number of steps. The type of conductivity of the substrate and the emission wavelength do not restrict the present invention.

Since the above embodiment is described only for examples, the present invention is not limited to the above embodiment and various modifications or alterations can be easily made therefrom by those skilled in the art without departing from the scope of the present invention.

What is claimed is:

1. A semiconductor laser device comprising a substrate, a resonator overlying said substrate, a waveguide overlying said substrate and optically coupled to said resonator, and a diffraction grating formed on said resonator or said waveguide, said diffraction grating including slits or grooves formed on an Al-oxidized region of an Al-containing oxidized semiconductor layer, said Al-oxidized region being formed by selectively oxidizing Al in said Al-containing oxidized semiconductor layer.

2. The semiconductor laser device as defined in claim 1, wherein the substrate is an InP substrate, the Al-containing oxidized semiconductor layer is an AlInAs layer.
